(19) United States
(12) Patent Application Publication
(10) Pub. No.: US 2024/0186381 A1
(43) Pub. Date: Jun. 6, 2024

(54) SILICON CARBIDE SUBSTRATE AND SILICON CARBIDE SEMICONDUCTOR DEVICE INCLUDING THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Hideyuki UEHIGASHI, Nisshin-shi (JP); Akiyoshi HORIAI, Nisshin-shi (JP)

(21) Appl. No.: 18/494,315

(22) Filed: Oct. 25, 2023

(30) Foreign Application Priority Data
Dec. 5, 2022 (JP) 2022-194322

(51) Int. Cl. H01L 29/16; H01L 21/02; H01L 21/20; H01L 29/417; H01L 29/66; H01L 29/78

(52) U.S. Cl. CPC H01L 29/1608; H01L 21/02378; H01L 21/2011; H01L 29/41766; H01L 29/66068; H01L 29/7813

(57) ABSTRACT

A silicon carbide substrate includes a substrate made of silicon carbide. An emission peak of the substrate at a wavelength of 650 to 750 nm is 4.5 times or more of an emission peak of the substrate at a wavelength of 385 to 408 nm in an electronic excitation. An integral value related to an emission peak of the substrate at a wavelength of 650 to 750 nm is 15 times or more of an integral value related to an emission peak of the substrate at a wavelength of 385 to 408 nm in an electronic excitation.

### CROSS REFERENCE TO RELATED APPLICATION

The present application claims the benefit of priority from Japanese Patent Application No. 2022-194322 filed on Dec. 5, 2022. The entire disclosure of the above application is incorporated herein by reference.

### TECHNICAL FIELD

The present disclosure relates to a silicon carbide (SiC) substrate and a SiC semiconductor device including the SiC substrate.

### BACKGROUND

Conventionally, a SiC semiconductor device made of SiC has been proposed. For example, a SiC semiconductor device including a metal oxide semiconductor field effect transistor (MOSFET) has been proposed.

### SUMMARY

According to an aspect of the present disclosure, a SiC substrate includes a substrate made of silicon carbide, in which an emission peak of the substrate at a wavelength of 650 to 750 nm is set to be 4.5 times or more of an emission peak of the substrate at a wavelength of 385 to 408 nm in an electronic excitation.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view illustrating a SiC semiconductor device according to an embodiment;

FIG. 2A is a photoluminescence image, in which a fluorescence of 420±10 nm is captured using an optical filter, when a SiC semiconductor device is made of a substrate having a carrier lifetime of 10 ns;

FIG. 2B is a photoluminescence image, in which a fluorescence of 420±10 nm is captured using an optical filter, when a SiC semiconductor device is made of a substrate having a carrier lifetime of 2.5 ns; and

FIG. 3 is a diagram illustrating a relationship between a wavelength and a PL intensity.

### DETAILED DESCRIPTION

Next, a relevant technology is described only for understanding the following embodiments. A SiC semiconductor device according to the relevant technology includes a substrate of n+-type, a buffer layer of n⁻-type having a lower impurity concentration than the substrate and disposed on the substrate, and a drift layer of n⁻-type having a lower impurity concentration than the buffer layer and disposed on the buffer layer. On the drift layer, a base layer of p-type is disposed. The buffer layer and the drift layer are formed of epitaxial layers.

In a surface layer portion of the base layer, a source region of n+-type is disposed. A plurality of trenches is provided to penetrate the source region and the base layer and reach the drift layer, and a gate insulating film and a gate electrode are sequentially disposed in each of the trenches. Accordingly, a trench gate structure is formed.

In the SiC semiconductor device, a parasitic diode is formed by a pn junction between the base layer and the drift layer.

In the SiC semiconductor device, a basal plane dislocation (hereinafter simply referred to as BPD) may be present in the substrate. If an injected hole reaches the BPD while the parasitic diode operates, the BPD may expand to a stacking fault (hereinafter simply referred to as SF).

In the SiC semiconductor device, an influence of the BPD on an element operation is small because the BPD is a linear defect, but an influence of the SF on an element operation is large because the SF is a planar defect and becomes a resistance component. Therefore, in the SiC semiconductor device, there is a possibility that an ON voltage becomes high.

The present disclosure provides a SiC substrate capable of suppressing expansion of the BPD into the SF, and a SiC semiconductor device using the SiC substrate.

According to an aspect of the present disclosure, a SiC substrate includes a substrate made of silicon carbide, in which an emission peak at a wavelength of 650 to 750 nm is set to be 4.5 times or more of an emission peak at a wavelength of 385 to 408 nm in an electronic excitation.

According to another aspect of the present disclosure, a SiC substrate includes a substrate made of silicon carbide, in which an integral value related to an emission peak at a wavelength of 650 to 750 nm is 15 times or more of an integral value related to an emission peak at a wavelength of 385 to 408 nm in an electronic excitation.

Accordingly, it is possible to suppress expansion of the BPD to the SF.

According to another aspect of the present disclosure, a SiC semiconductor device includes the SiC substrate and an epitaxial layer formed on the SiC substrate. A part of the epitaxial layer has a thickness of 4 to 40 μm and an impurity concentration of 1.0×10¹⁵ to 1.0×10¹⁹ cm⁻³.

Accordingly, it is possible to obtain a SiC semiconductor device in which expansion of the BPD into the SF is suppressed.

Hereinafter, embodiments of the present disclosure will be described with reference to the drawings. In the following embodiments, the same or equivalent parts are denoted by the same reference numerals.

### First Embodiment

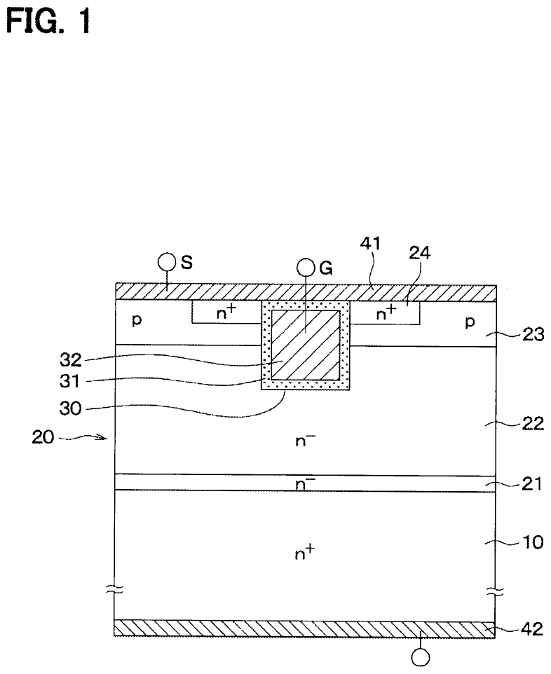

A first embodiment will be described with reference to the drawings. In the present embodiment, a SiC semiconductor device includes a metal oxide semiconductor field effect transistor (MOSFET) serving as a semiconductor element. Although not particularly illustrated, the SiC semiconductor device includes a cell region and an outer peripheral region formed to surround the cell region. The MOSFET shown in FIG. 1 is formed in the cell region of the SiC semiconductor device.

The SiC semiconductor device includes an n⁺-type substrate 10 made of SiC. An epitaxial layer 20 made of SiC is disposed on a surface of the substrate 10. The epitaxial layer 20 of the present embodiment has a buffer layer 21 of n⁻-type, a drift layer 22 of n⁻-type, and a base layer 23 of p-type which are stacked in this order. The epitaxial layer 20 has a thickness of about 4 to 40 μm in a thickness direction along the normal direction to the surface of the substrate 10. The epitaxial layer 20 has an impurity concentration of 1.0×10¹⁵ to 1.0×10¹⁹ cm⁻³.

In a surface layer portion of the base layer 23, a source region 24 of n⁺-type is disposed. The source region 24 is formed by performing ion implantation on the surface layer portion of the base layer 23 or forming a groove in the base layer 23 and disposing an epitaxial layer of n-type in the groove.

The substrate 10 has a specific resistance within a range of 1 mΩ·cm or more and 30 mΩ·cm or less (for example, 20 mΩ·cm). The substrate 10 has a front surface of a (0001) Si plane, and has an off angle of 0.5 to 5 degrees with respect to the (0001) Si plane. The substrate 10 has an n-type impurity concentration of, for example, 5.0×10¹⁸ to 1.0×10²⁰ cm⁻³. Further, in the substrate 10, the emission peak at the wavelength of 650 to 750 nm is 4.5 times or more of the emission peak at the wavelength of 385 to 408 nm in electronic excitation, which will be specifically described later. In the present embodiment, the substrate 10 corresponds to a silicon carbide substrate. In the present embodiment, the substrate 10 forms a drain layer of the MOSFET.

The buffer layer 21 has, for example, an n-type impurity concentration of 1.0×10¹⁸ to 1.0×10¹⁹ cm⁻³. The drift layer 22 has an n-type impurity concentration of, for example, 1.0×10¹⁵ to 5.0×10¹⁶ cm⁻³.

The base layer 23 is a portion where a channel region is formed, and has, for example, a p-type impurity concentration of about 3.0×10¹⁷ cm⁻³ and a thickness of 0.5 to 2 μm. The source region 24 has a higher impurity concentration than the drift layer 22. For example, an n-type impurity concentration in a surface layer portion of the source region 24 is about 2.5×10¹⁸ to 1.0×10¹⁹ cm⁻³, and the source region 24 has a thickness of 0.5 to 2 μm. The thicknesses and the like of the drift layer 22, the base layer 23, and the source region 24 may be set to predetermined values but not limited to the above examples.

The trench 30 is formed to penetrate the base layer 23 and the source region 24 so as to reach the drift layer 22. The base layer 23 and the source region 24 are disposed in contact with a side surface of the trench 30. Although only one trench 30 is illustrated in FIG. 1, the trench 30 is actually formed in a stripe shape in which plural trenches are arranged at equal interval in a left-right direction on a paper surface of FIG. 1.

A gate insulating film 31 is formed on a wall surface of the trench 30. A gate electrode 32 made of doped polysilicon is formed on a surface of the gate insulating film 31. The trench 30 is filled with the gate insulating film 31 and the gate electrode 32. In the present embodiment, a trench gate structure is configured in this manner.

An upper electrode 41 serving as a source electrode is disposed on the epitaxial layer 20, and is insulated from the gate electrode 32 and connected to the base layer 23 and the source region 24. In the present embodiment, the upper electrode 41 is made of metals such as Ni and Al. A portion of the metals in contact with a portion forming an n-type SiC (that is, the source region 24) is made of a metal capable of making ohmic contact with the n-type SiC. In addition, at least a portion of the metals in contact with a portion forming a p-type SiC (that is, the base layer 23) is made of a metal capable of making ohmic contact with the p-type SiC.

A lower electrode 42 serving as a drain electrode electrically connected to the substrate 10 is formed on a back surface of the substrate 10. In the present embodiment, with such a structure, MOSFET of an n-channel type inverted trench gate structure is formed. The cell region is formed by arranging plural MOSFETs.

The basic structure of the semiconductor device according to the present embodiment is described above. In such a SiC semiconductor device, when a predetermined gate voltage is applied to the gate electrode 32, an inversion layer is formed in a portion of the base layer 23 in contact with the trench 30, and a current flows between the upper electrode 41 and the lower electrode 42. That is, a current flows along the stacking direction of the substrate 10 and the epitaxial layer 20.

Although not particularly illustrated, the substrate 10 may include a basal plane dislocation (BPD). In the SiC semiconductor device in which the above-described MOSFET is formed, holes are injected when a parasitic diode operates, and reach the basal plane dislocation. In this case, the basal plane dislocation may expand to a stacking fault (SF).

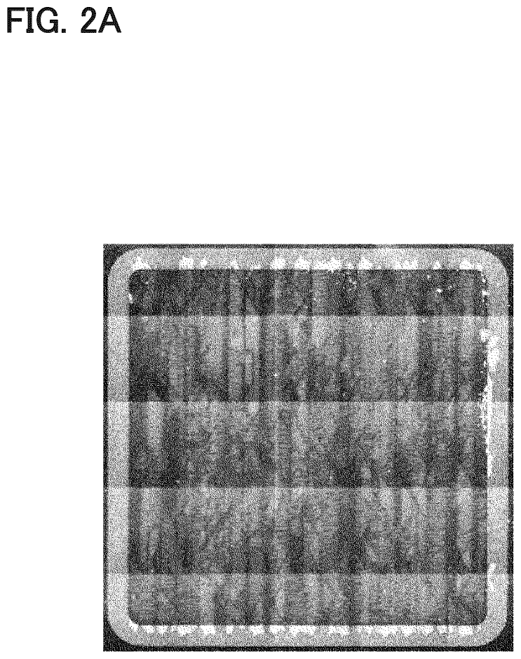

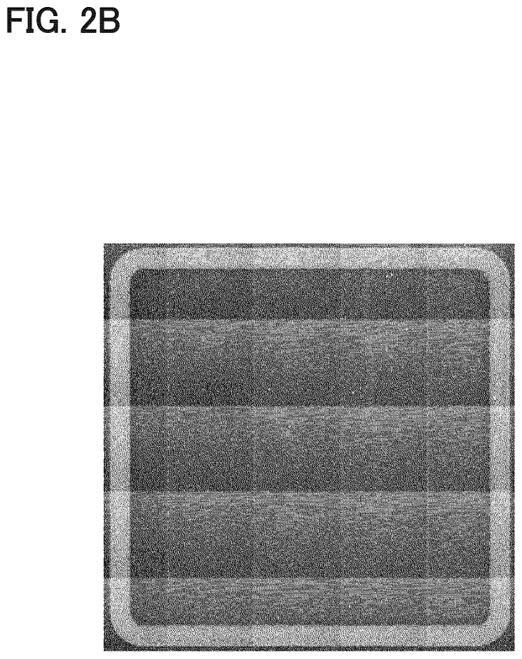

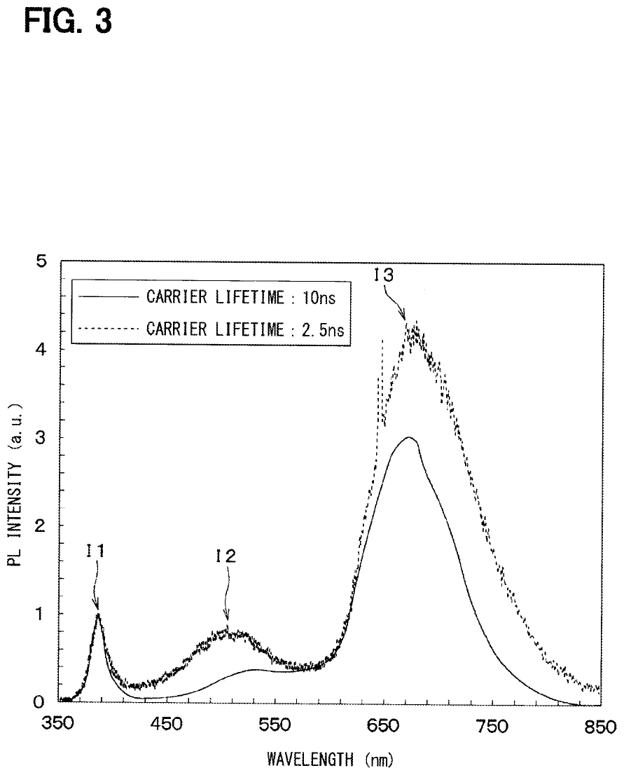

Here, in order to suppress the BPD from becoming the SF, it is useful to form a defect level that becomes a minority carrier killer. Then, the present inventors studied the relationship between the carrier lifetime depending on the minority carrier killer amount and the expansion of the BPD to the SF, and obtained the results shown in FIGS. 2A, 2B, and 3.

As shown in FIG. 2A, when the SiC semiconductor device is configured using a substrate having a carrier lifetime of 10 ns, it was observed that the BPD was expanded to the SF. As shown in FIG. 2B, when the SiC semiconductor device is configured using a substrate having a carrier lifetime of 2.5 ns, it was not confirmed that the BPD was expanded to the SF. Therefore, in order to restrict the BPD from expanding to the SF, the SiC semiconductor device may be configured using the substrate 10 having a carrier lifetime of 2.5 ns or less. The carrier lifetime is a result measured by a μ-PCD (abbreviation of Photo Conductivity Decay) method. The carrier lifetime of 2.5 ns is a resolution lower limit value of the current μ-PCD method.

However, the μ-PCD method is not a widely distributed method at present. Therefore, there is a demand for a method capable of confirming whether or not the BPD expands to the SF by a simpler method. Therefore, the present inventors have obtained the following findings by focusing on an emission peak at the time of electronic excitation, which is widely used in current semiconductor evaluation.

Hereinafter, an example using a photo luminescence (PL) measurement will be described. In the PL method, an object to be measured (that is, the substrate 10) is irradiated with light having energy equal to or higher than the band cap, and the intensity of light generated when excited electrons return to the ground state is measured to grasp the state of the object. The intensity of light changes depending on the material of the object, the presence or absence of a defect, and the like.

When the PL method using SiC as a target object is performed, the following peaks occur. Specifically, as shown in FIG. 3, the band edge emission peak I1 is generated due to the material in the wavelength range of 385 to 408 nm. Further, the impurity emission peak I2 is generated due to the impurity in the wavelength range of 480 to 580 nm. Furthermore, the carrier lifetime emission peak I3 is generated due to the carrier lifetime in the wavelength range of 650 to 750 nm.

As shown in FIG. 3, when the PL measurement is performed on the SiC semiconductor device using the substrates 10 having different carrier lifetimes described with reference to FIGS. 2A and 2B, the followings are confirmed. First, it is confirmed that the carrier lifetime emission peak I3 of the SiC semiconductor device using the substrate 10 having a carrier lifetime of 2.5 ns is larger than that of the SiC semiconductor device using the substrate 10 having a carrier lifetime of 10 ns. That is, it is confirmed that the shorter the carrier lifetime, the larger the carrier lifetime emission peak I3. The band edge emission peak I1 depends on the material and thus does not change depending on the carrier lifetime.

In the substrate 10 having a carrier lifetime of 2.5 ns, it is confirmed that the carrier lifetime emission peak I3 is 4.5 times of the band edge emission peak I1. That is, it is confirmed that, in the substrate 10, when the carrier lifetime emission peak I3 is 4.5 times or more of the band edge emission peak I1, it is difficult to expand from the BPD to the SF. Therefore, in the substrate 10 of the present embodiment, the carrier lifetime emission peak I3 is 4.5 times or more of the band edge emission peak I1.

Such a PL measurement is performed before the epitaxial layer 20 is grown on the substrate 10. However, the PL measurement may be performed after the epitaxial layer 20 is grown on the substrate 10 to form the MOSFET. In this case, for example, when the SiC semiconductor device of FIG. 1 is manufactured, the following process may be performed. That is, first, characteristic inspections such as an on-resistance test and a forward conduction test are performed, and then the lower electrode 42 and the like are removed by wet etching. Thereafter, the PL measurement may be performed by irradiating the substrate 10 with light from the side opposite to the epitaxial layer 20.

In addition, although the ratio between the band edge emission peak I1 and the carrier lifetime emission peak I3 has been described above, this can be indicated by the ratio of integrated values. In this case, as shown in FIG. 3, the integrated intensity value obtained by integrating the intensity at the wavelength of 650 to 750 nm is 15 with respect to the integrated intensity value obtained by integrating the intensity at the wavelength of 385 to 408 nm. Therefore, in the substrate 10, the integrated intensity value at the wavelength of 650 to 750 nm may be set to be 15 times or more of the integrated intensity value at the wavelength of 385 to 408 nm.

The substrate 10 is prepared as follows. First, the carrier lifetime emission peak I3 depends on crystal defects included in the substrate 10, and becomes shorter as the number of crystal defects increases. Examples of the crystal defect affecting the carrier lifetime emission peak I3 include atomic vacancies. That is, in order to control the carrier lifetime emission peak I3, it is sufficient to control the number of atomic vacancies.

The substrate 10 is usually obtained by cutting a SiC ingot. The present inventors have found that the density of atomic vacancies can be changed depending on the manufacturing conditions of the SiC ingot. Specifically, while the SiC ingot is obtained by a high temperature chemical vapor deposition (CVD) method or a sublimation method, the concentration of crystal defects changes depending on the temperature at the time of manufacturing. More specifically, the SiC ingot is configured by arranging a seed substrate in a chamber, and introducing a reaction gas such as silane or propane into the chamber to grow an epitaxial layer on the seed substrate while controlling the temperature in the chamber by a heating device arranged around the chamber. At this time, as the growth temperature of the epitaxial layer increases, the crystal defects tend to increase. Then, the present inventors have found that it is possible to manufacture the substrate 10 (that is, the SiC ingot) having a peak ratio of 4.5 times or more by growing the epitaxial layer under the condition that the growth surface has the temperature in the vicinity of about 2500° C. Therefore, in the present embodiment, a SiC ingot is prepared, in which an epitaxial layer is grown under a condition that the growth surface has a temperature about 2500° C., and the substrate 10 is prepared by cutting the SiC ingot.

After the SiC ingot is manufactured in the chamber, the SiC ingot is taken out after the temperature in the chamber is lowered. At this time, in general, the temperature in the chamber is gradually decreased while controlling the heating device, but the driving of the heating device may be stopped and the temperature may be naturally decreased to rapidly cool the SiC ingot. Further, in order to increase the temperature lowering rate, a chamber having a small heat capacity may be used. As described above, crystal defects can be increased by rapidly cooling the SiC ingot.

According to the present embodiment, in the substrate 10, the carrier lifetime emission peak I3 at the wavelength of 650 to 750 nm is 4.5 times or more of the band edge emission peak I1 at the wavelength of 385 to 408 nm in electronic excitation. Therefore, it is possible to restrict the BPD from expanding to the SF. In addition, by grasping the band edge emission peak I1 and the carrier lifetime emission peak I3 in advance in the state of the substrate 10, it is possible to determine whether or not there is a high possibility that the BPD expands to the SF later. Therefore, a highly reliable SiC semiconductor device can be obtained by configuring the SiC semiconductor device using the substrate 10 in which the carrier lifetime emission peak I3 at the wavelength of 650 to 750 nm is 4.5 times or more of the band edge emission peak I1 at the wavelength of 385 to 408 nm.

In the present embodiment, the specific resistance of the substrate 10 is 30 mΩ·cm or less, and the n-type impurity concentration is within a range between 5.0×10¹⁸ to 1.0×10²⁰ cm⁻³. A part of the epitaxial layer 20 has an impurity concentration of 1.0×10¹⁵ to 1.0×10¹⁹ cm⁻³ and a film thickness of 4 to 40 μm. The buffer layer has an impurity concentration of 1.0×10¹⁸ to 1.0×10¹⁹ cm⁻³, and the drift layer 22 has an impurity concentration of 1.0×10¹⁵ to 5.0×10¹⁶ cm⁻³. Therefore, it is possible to obtain a MOSFET having currently desired characteristics.

### Second Embodiment

The second embodiment is different from the first embodiment in that an impurity is added to the substrate 10. The remaining configurations are similar to those of the first embodiment and will thus not be described repeatedly.

The basic configuration of the present embodiment is the same as that of the first embodiment. In the present embodiment, the substrate 10 contains at least one impurity selected from a group consisting of boron (B), aluminum (AI), titanium (Ti), vanadium (V), sulfur (S), iron (Fe), niobium (Nb), and tantalum (Ta). The impurity is appropriately added when the SiC ingot to be the substrate 10 is prepared.

According to the present embodiment, in the substrate 10, the carrier lifetime emission peak I3 at the wavelength of 650 to 750 nm is 4.5 times or more of the band edge emission peak I1 at the wavelength of 385 to 408 nm in electronic excitation. Therefore, the same effects as those of the first embodiment can be obtained.

In the present embodiment, the substrate 10 contains at least one impurity selected from a group consisting of boron (B), aluminum (AI), titanium (Ti), vanadium (V), sulfur (S), iron (Fe), niobium (Nb), and tantalum (Ta). Therefore, since the impurity functions as minority carrier killers, it is possible to further suppress the expansion of the BPD to the SF.

### Other Embodiments

Although the present disclosure has been described in accordance with the embodiments, it is understood that the present disclosure is not limited to such embodiments or structures. The present disclosure encompasses various modifications and variations within the scope of equivalents. In addition, various combinations and forms, and further, other combinations and forms including only one element, or more or less than these elements are also within the sprit and the scope of the present disclosure.

In each of the embodiments, the MOSFET has the n-channel type trench gate structure in which a first conductivity type is n-type and a second conductivity type is p-type. However, the semiconductor device may include a MOSFET with a p-channel type trench gate structure in which the conductivity type of each component is inverted with respect to the n-channel type.

In each of the embodiments, the SiC semiconductor device includes the MOSFET. However, the SiC semiconductor device may include a Schottky diode or pn diode.

Furthermore, in each of the embodiments, the substrate 10 is defined based on the peak ratio obtained by the PL measurement. However, the measurement is not limited to PL measurement while the ratio is based on light obtained by electronic excitation. For example, the substrate 10 may be defined based on an emission peak obtained by a cathode luminescence (CL) measurement, or on an emission peak obtained by an electro luminescence (EL) measurement. In these methods, according to the study by the present inventors, when the carrier lifetime emission peak I3 is 4.5 times or more of the band edge emission peak I1, it is possible to suppress the expansion of the BPD to the SF.

What is claimed is:

1. A silicon carbide substrate comprising:
a substrate made of silicon carbide, wherein
an emission peak of the substrate at a wavelength of 650 to 750 nm is 4.5 times or more of an emission peak of the substrate at a wavelength of 385 to 408 nm in an electronic excitation.

2. A silicon carbide substrate comprising:
a substrate made of silicon carbide, wherein
an integral value related to an emission peak of the substrate at a wavelength of 650 to 750 nm is 15 times or more of an integral value related to an emission peak of the substrate at a wavelength of 385 to 408 nm in an electronic excitation.

3. The silicon carbide substrate according to claim 1, wherein the substrate has a specific resistance of 30 mΩ·cm or less.

4. The silicon carbide substrate according to claim 1, wherein the substrate is an n-type substrate and has an impurity concentration within a range of 5.0×10¹⁸ to 1.0×10²⁰ cm⁻³.

5. The silicon carbide substrate according to claim 1, wherein the substrate contains impurities including at least one element selected from a group consisting of boron, aluminum, titanium, vanadium, sulfur, iron, niobium, and tantalum.

6. A silicon carbide semiconductor device comprising:
the silicon carbide substrate according to claim 1; and
an epitaxial layer formed on the silicon carbide substrate, wherein
a part of the epitaxial layer has a thickness within a range of 4 to 40 μm and has an impurity concentration of 1.0×10¹⁵ to 1.0×10¹⁹ cm⁻³.

7. The silicon carbide semiconductor device according to claim 6, wherein
the epitaxial layer includes a buffer layer adjacent to the silicon carbide substrate and a drift layer positioned on the buffer layer,
the buffer layer has an n-type impurity concentration of 1.0×10¹⁸ to 1.0×10¹⁹ cm⁻³, and
the drift layer has an n-type impurity concentration of 1.0×10¹⁵ to 5.0×10¹⁶ cm⁻³.

8. The silicon carbide semiconductor device according to claim 6, wherein a semiconductor element is formed, through which a current flows in a stacking direction of the silicon carbide substrate and the epitaxial layer.
